(19) United States
(12) Patent Application Publication
(10) Pub. No.: US 2021/0207264 A1
(43) Pub. Date: Jul. 8, 2021

(54) VACUUM-COATING SYSTEM AND METHOD FOR COATING A BAND-TYPE MATERIAL

(71) Applicant: SMS group GMBH, Düsseldorf (DE)

(72) Inventors: Lutz KÜMMEL, Jüchen (DE); Thomas DAUBE, Duisburg (DE)

(73) Assignee: SMS group GMBH, Düsseldorf (DE)

(21) Appl. No.: 17/058,841

(22) PCT Filed: Apr. 18, 2019
(86) PCT No.: PCT/EP2019/060153

§ 371 Date: Nov. 25, 2020

(30) Foreign Application Priority Data
May 28, 2018 (DE) 10 2018 208 335.5
Sep. 5, 2018 (DE) 10 2018 215 100.8

(51) Int. Cl. C23C 14/56; C23C 14/16; C23C 14/24; C23C 14/50; B65H 23/038; B65H 23/02; B65H 23/032

(52) U.S. Cl. CPC C23C 14/568; C23C 14/16; C23C 14/24; C23C 14/50; B65H 2701/173; B65H 23/038; B65H 23/0204; B65H 23/0322; B65H 2301/5114; C23C 14/562

(57) ABSTRACT

A method and a vacuum-coating system for coating a band-type material, in particular made of metal. For this, the band-type material is moved, via a conveying section, in a transport direction and is vacuum-coated within a coating chamber, in which a vacuum is applied. A position of the band-type material is adjusted and/or aligned as relates to a center of the conveying section by means of at least one band position control device, which is arranged within the coating chamber.

The invention relates to a vacuum-coating system according to the preamble of claims 1 and 3, and a method for coating a band-type material according to the preamble of claim 17.

During the production of steel bands, there are width changes in the band over the length during both hot rolling and cold rolling. This is caused by so-called “expansion” which results in an increase of a few millimeters in the width of the rolled band due to the rolling pass. The differing expansion over the length of the steel band is normally due to fluctuations in tension within the system with which the steel strip is being processed.

A further problem when rolling steel bands is that waves on the edge or in the center may result from the rolling process due to the different lengthening over the cross-section.

During the production of band-type material, e.g. in the form of steel bands, it is known according to the prior art to galvanize the surfaces of this band-type material. This can take place by means of a vacuum vapor deposition process as is known, for example, from DE 30 35 000 A1, DE 195 27 515 C1, or DE 197 35 603 C1. This vacuum vapor deposition process also includes so-called PVD technology, which is explained, for example, in DE 10 2009 053 367 A1.

In the aforementioned vacuum vapor deposition process, the coating of the band-type material takes place in a vacuum, wherein the band-type material is supplied to a chamber or the like, in which a vacuum exists or is generated, by means of a lock and/or a system of diaphragm elements. The sealing of the vacuum generated in the chamber relative to the environment is usually via sealant in the form of diaphragm elements, which is described, for example, in WO 2008/049523 A1 in connection with a band lock. According to EP 1 004 369 B1, such a seal can also be realized by a lock with a plurality of rollers, wherein at least one roller is arranged offset with respect to at least two other rollers and can be adjusted in its distance to these two other rollers to provide a seal for the band-type material, which is moved between these rollers.

If a band-type material is coated according to the principle of the vacuum vapor deposition process, the sealing of the vacuum against the environment is of great importance. For this purpose, the vacuum chamber, in which the coating of the band-type material is implemented, has locks on the inlet side and outlet side. If the band-type material has imperfections over its band length, such as a non-constant width (sword shape) or flatness defects, which may arise due to upstream heat treatment processes, this can cause the band-type material to go off-course on the conveying section of a vacuum-coating system, which is critical with respect to a necessary sealing of the vacuum, particularly in the region of the locks of a vacuum chamber of this system. Imprecise positioning of the band-type material on the conveying section can either lead to increased wear or even to a break in the vacuum in the region of the locks of the vacuum chamber, whereby the coating process under vacuum is disturbed. In addition, such imperfections within the vacuum chamber result in changed distances between the surfaces of the band-type material to be coated and the coating and cleaning modules, whereby the vacuum coating process is also impacted.

Accordingly, the object upon which the invention is based is to optimize the coating of band-type material under vacuum with simple means and to achieve improved process reliability for this.

This object is achieved by means of a vacuum-coating system according to claims 1 and 3 and by means of a method having the features listed in claim 17. Advantageous further embodiments of the invention are defined in the dependent claims.

A vacuum-coating system according to the present invention is used for coating a band-type material, in particular of metal, and comprises a conveying section with transport means, in particular in the form of rollers on which the band-type material can be moved in a transport direction; a coating chamber in which vacuum can be generated, wherein the coating chamber has an inlet region and an outlet region and can thereby be traversed by the band-type material along or on the conveying section in the transport direction; an entry lock which is provided in the inlet region of the coating chamber; and an exit lock which is provided in the outlet region of the coating chamber.

The vacuum-coating system also comprises at least one band position control device, with which a position of the band-type material can be adjusted, preferably aligned, as relates to a center of the conveying section. Such a band position control device is arranged either within the coating chamber and/or upstream of the coating chamber and outside thereof—as seen in the transport direction of the band-type material.

In the same manner, the invention also provides for a method for coating a band-type material, particularly made of metal, in which the band-type material is moved in a transport direction via a conveying section and is vacuum-coated within a coating chamber, in which a vacuum is applied. In this case, the band-type material is adjusted, preferably aligned, with its band center as relates to a center of the conveying section, by means of at least one band position control device which is arranged either within the coating chamber and/or upstream of the coating chamber and outside thereof—as seen in the transport direction of the band-type material.

The invention is based on the essential knowledge that the band-type material is adjusted and preferably aligned as relates to a center of the conveying section, i.e. perpendicular to its transport direction, by means of the band position control device. This ensures that the band-type material is moved optimally centered on the conveying section, particularly within the coating chamber, such that, within the coating chamber, a collision or contact between the band-type material and the sidewalls is prevented and an optimum coating result is achieved. To this end, it is expedient when such a band position control device is integrated into the coating chamber, i.e. is arranged within the coating chamber. In the event that the band-type material should deviate laterally from the conveying section in its position or “go off-course” during its movement through the coating chamber, this can be effectively counteracted with the band position control device arranged within the coating chamber.

As a supplement and/or alternative, it is also possible for a band position control device to be arranged upstream of the coating chamber—as seen in the transport direction of the band-type material. The functional principle of such a band position control device arranged outside of the coating chamber corresponds identically to a band position control device which is arranged within the coating chamber as previously explained, namely that the position of the band-type material is hereby preferably aligned as relates to a center of the conveying section. This leads to the advantage that the band-type material is already correctly aligned as relates to its position on the conveying section when it reaches the entry lock of the coating chamber and enters it during its movement in the transport direction. This provides an interference-free and substantially wear-free contact between the band-type material and sealing means provided at the entry lock, whereby a reliable sealing of the vacuum to the environment is ensured within the coating chamber.

In an advantageous refinement of the invention, a band position control device may also be arranged upstream of the coating chamber—as seen in the transport direction of the band-type material. Thus, after it is coated, the band-type material is again checked with respect to a correct position as relates to a center of the conveying section and aligned correctively as needed. This ensures that the coated band-type material can be wound on a winding device without interference or can optionally be intermediately stored in a storage unit arranged upstream thereof.

In an advantageous refinement of the invention, a control unit and at least one position sensor are provided, wherein there is a signal connection to said control unit between a band position control device and one such position sensor. The position sensor can be used to detect and/or determine a position of the band-type material on the conveying section, particularly as relates to a center region of the conveying section. In the event that a deviation is detected in the position of the band-type material as relates to the center region of the conveying section, a band position control device can be suitably actuated by the control unit, as a function of the signals of the position sensor, for the purpose of a correction and/or alignment of the position of the band-type material on the conveying section.

The present invention advantageously enables a coating, under vacuum, of band-type material which consists of steel band and has a structural proportion of at least 10% martensite. Such a steel band may further contain 0.1-0.4% carbon, 0.5-2.0% silicon, and/or 1.5-3.0% manganese. Such steels may be present as dual-phase steels (DP), complex-phase steel (CP), quenching and partitioning steels (Q&P), or as martensitic steels (MS), each of which having a different content of martensites (with at least 10%).

A preferred embodiment of the invention is described in the following in detail by means of schematically simplified drawings. The following is shown:

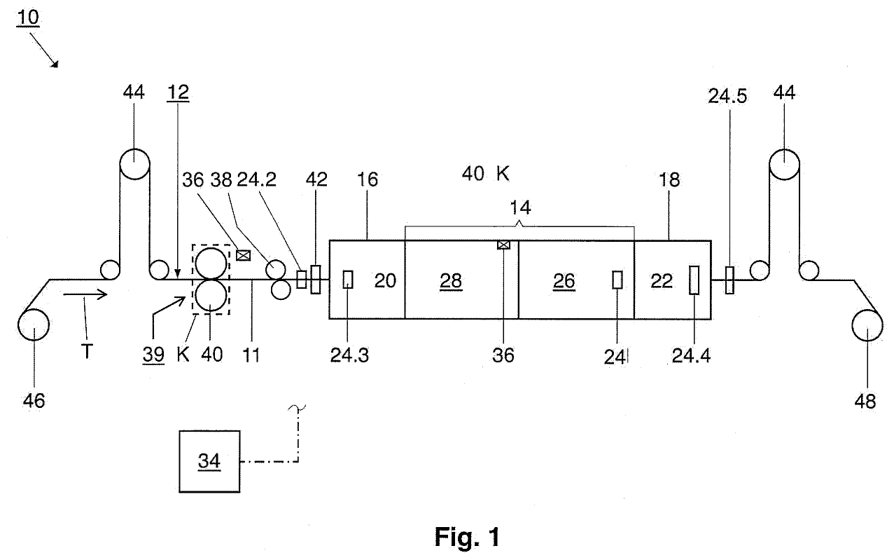

FIG. 1 a schematically simplified side view of a vacuum-coating system according to the invention, with which a method according to the present invention can also be implemented;

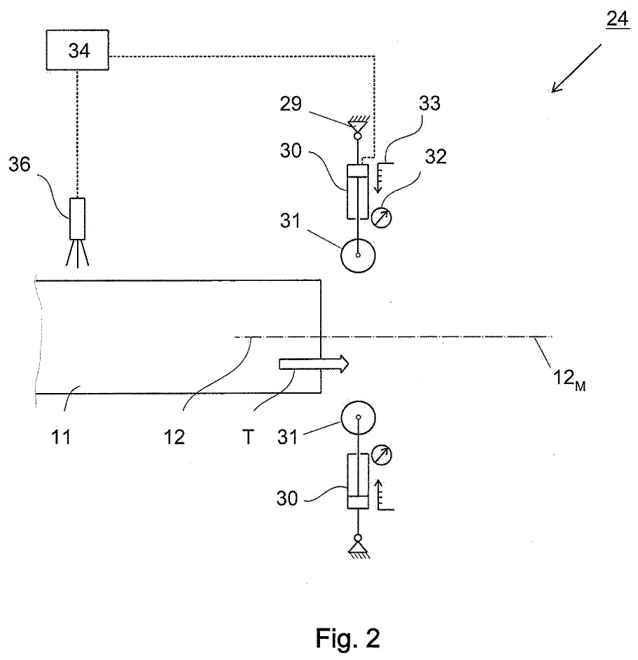

FIGS. 2-4 each show schematically simplified views of various embodiments of a band position control device which is used with a vacuum-coating system from FIG. 1; and

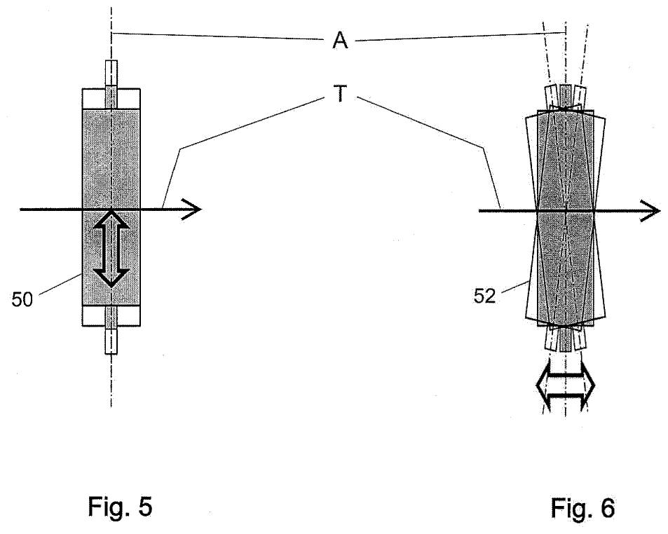

FIG. 5, FIG. 6 each show a simplified top view of a control roller according to further embodiments of the invention.

The present invention provides for a vacuum-coating system 10, with which a band-type material 11 can be provided with a coating on at least one side thereof, preferably on both sides (upper side and lower side). Accordingly, a method particularly for coating the band-type material 11 can also be implemented with such a vacuum-coating system 10. Equivalent features in the two figures of the drawing are each provided with the same reference numbers. At this juncture, particular reference is made to the fact that the drawing is merely simplified and particularly not shown to scale.

The band-type material 11 may consist of metal, particularly of steel or stainless steel, or corresponding alloys thereof. Furthermore, reference is made to the fact that the band-type material 11, which is coated with the vacuum-coating system 10, may be a hot band or cold band.

The vacuum-coating system 10, the individual components thereof, and the functional principle thereof are explained in detail in the following:

The vacuum-coating system 10 comprises a conveying section 12 with (not shown) transport means, e.g. in the form of rollers, on which the band-type material is moved in a transport direction T. In this case, the band-type material 11 is unwound by a first winding device 46 at the infeed of the conveying section 12, wherein the band-type material 11—after implementation and/or completion of the desired coating—is wound up again by a second winding device 48 at the outfeed of the conveying section 12. (Band) storage units 44, with or in which the band-type material 11 can be stored, can be provided directly downstream of the first winding device 46 and upstream of the second winding device 48. The band-type material 11 is moved and/or transported within the conveying section 12 in the direction of movement T, namely from the first winding device 46 in the direction of the second winding device 48.

A coating chamber 44, through which the band-type material 11 is moved, is arranged along the conveying section 12. To this end, the coating chamber 14 has an inlet region 16 and an outlet region 18, wherein an entry lock 20 is provided in the inlet region 16 and an exit lock 22 is provided in the outlet region 18. A vacuum is generated in the coating chamber 14. In this case, the entry lock 20 and the exit lock 22 ensure suitable sealing of this vacuum to the external environment upon the simultaneous movement of the band-type material 11 along the conveying section 12 and/or through these two locks 20, 22.

The coating chamber 14 is formed in multiple parts and has a coating part 26 and a cleaning part 28. As previously explained, both of these parts, 26 and 28, are placed under vacuum. The actual coating of the band-type material 11 is carried out in the coating part 26, e.g. according to the principle of PVD (=physical vapor deposition), either on one side of the band-type material or on both sides thereof.

At least one band position control device 24 may be arranged within the coating chamber 14, e.g. within the coating part 26, as is shown in FIG. 1. As a supplement or alternative, it is possible to arrange such a band position control device 24 in the cleaning part 28.

According to a further embodiment of the invention, it is possible to arrange a band position control device 24.2 upstream of the entry lock 20—as seen in the transport direction T of the band-type material 11. With respect to this, reference is made to the fact that a combination with the aforementioned embodiment is also possible, wherein a band position control device 24 is arranged within the coating chamber 14 and a band position control device 24.2 is arranged in the region upstream of the entry lock 20.

It may optionally also be provided that a band position control device 24.3 is also provided in the region of the entry lock 20, and a further band position control device 24.4 is provided in the region of the exit lock 22. Finally, it is also possible to arrange a further band position control device 24.5 upstream of the exit lock 22—as seen in the transport direction T of the band-type material 11.

Various embodiments of a band position control device 24 (and/or 24.2, 24.3, 24.4, 24.5) and the functional principal thereof are explained in detail with reference to FIGS. 2 to 6 as follows.

FIG. 2 simply shows the essential components of an embodiment of the band position control device 24 in conjunction with a top view of the band-type material 11, wherein the remaining parts of the vacuum-coating system 10 have been omitted from FIG. 1 for the sake of simplicity. The conveying section 12 is simply indicated by a dashed line in FIG. 2, wherein a center of this conveying section is designated as 12_{M}. An actuator 30, on the front end of which a contact roller 31 is rotatably mounted, is attached to a bearing 29 or part of a housing of the coating chamber 14. The actuator 30 is formed in the manner of a hydraulic cylinder, wherein, as an alternative thereto, an actuator is possible in the form of an electric linear motor or the like—having the same functionality. A movement of the contact roller 31 in the direction of the band-type material 1 perpendicular as relates to the transport direction T thereof is possible by means of the actuator 30.

The position of the band-type material 11 on the conveying section 12 can be detected by means of a position sensor 36, which is connected to a control unit 34 using signals (symbolically indicated by a dotted line in FIG. 2). In this respect, the function of a band-position detection element corresponds to the position sensor 36. Such a position sensor 36 may preferably be formed as a distance meter or the like, e.g. in the form of a laser sensor.

The actuation of an actuator 30 can take place in a force-controlled and/or distance-controlled manner. To this end, one pressure sensor 32 and one distance sensor 33 are provided for each actuator 30. The actuator is also connected to the control unit 34 with signals. Accordingly, the actuation of the actuator 30 can take place by means of the control unit 34 as a function of the signals of the position sensor 36.

The top view from FIG. 2 shows that an actuator 30 is arranged with a contact roller 31 attached thereto on both sides of the conveying section 12.

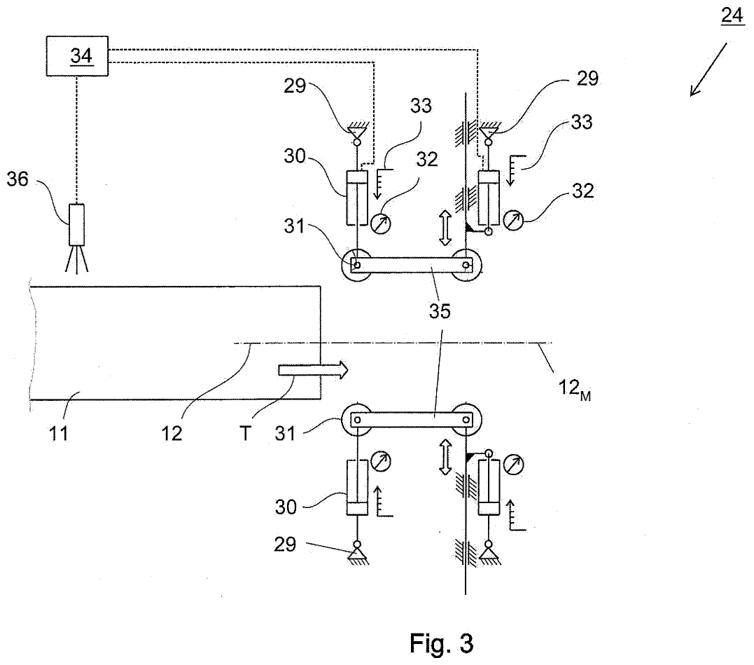

FIG. 3 shows a further embodiment for the band position control device 24. In contrast to the embodiment from FIG. 2, in this case, two contact rollers 31 are provided on each side of the conveying section 12, which contact rollers are rotatably attached to a guide ruler 35. Two actuators 30, e.g. in the form of hydraulic cylinders, are provided per guide ruler 35, which actuators can be connected to the control unit 34 with signals and thereby force-controlled and/or distance-controlled as a function of the signals of the position sensor 36.

With the embodiments according to FIGS. 2 and 3, the contact rollers 31 are used, as needed, to be positioned at the band edges of the band-type material 11, perpendicular to the transport direction T, and thus placed to have contact—by means of a corresponding actuation of the actuator 30—in order to correct and/or align a position of the band-type material 11 as relates to the center 12_{M} of the conveying section 12.

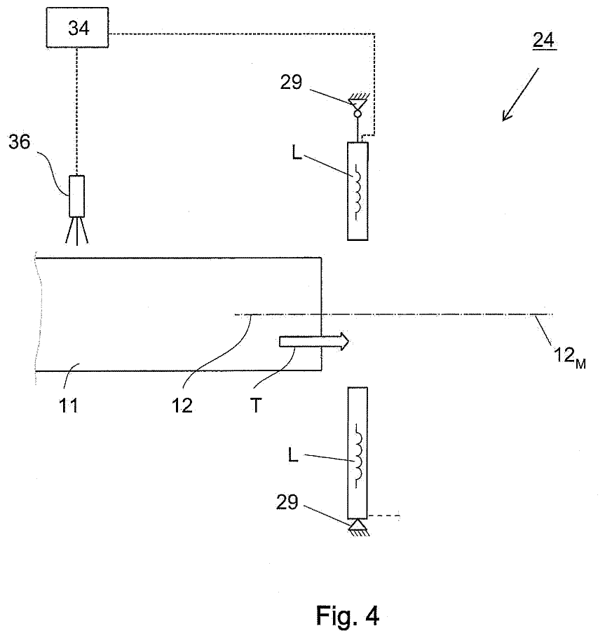

FIG. 4 shows a further embodiment for the band position control device 24, in which an energizable coil L is provided on both sides of the conveying section 12, which coil is attached to a bearing 29 or housing part of the coating chamber 14. These coils L are connected to the control unit 34 via signals such that they can be actuated and/or energized as a function of the signals of the position sensor 36. Due to the energizing of these coils L, a magnetic field or an electromagnetic alternating field is generated adjacent the conveying section 12, with the alternating field particularly interacting with the band-type material 11 when it consists of steel or a steel alloy. Specifically, this means that this interaction causes a repulsion between the energized coils L and the band-type material 11 consisting of steel. Due to this interaction and/or repulsion, it can be achieved, in the same manner as with the contact rollers 31, that a position of the band-type material 11 is corrected and/or aligned as relates to the center 12_{M} of the conveying section 12.

The previously explained embodiments of a band position control device 24 according to FIGS. 2-4 then function as follows:

In a starting state, the contact rollers 31 do not have contact with the band edges of the band-type material 11, in the embodiments from FIG. 2 and FIG. 3. In the same manner, the coils L are rendered currentless in the embodiment from FIG. 4 such that no magnetic field is acting on the band-type material 11.

During operation of the vacuum-coating system 10 and a movement of the band-type material 11 along the conveying section 12, if it is determined, by means of the position sensor 36, that the band-type material 11 has irregularities over its width, i.e. perpendicular to the transport direction T and/or is not traveling precisely in the center 12_{M} of the conveying section 12, the actuators 30 are actuated and/or the coils L are energized by means of the control unit 34, such that a position of the band-type material 11 on the conveying section 12 is suitably corrected due to the placement of the contact rollers 31 on the band edges of the band-type material 11 and/or due to the interaction of the generated magnetic fields with the band consisting of steel. As a result of this, the band movement of the band-type material 11 is corrected on the conveying section 12 perpendicular or transverse as relates to the transport direction T. In this context, reference is made to the fact that the contact rollers 31 only have contact with the band edges and/or lateral edges of the band-type material 11 as long as is necessary for a correction of the position of the band-type material 11 on the conveying section 12 as relates to the center 12_{M} thereof. In other words, the contact rollers 31 can again be moved away from the band edges of the band-type material 11 and/or moved away therefrom perpendicular as relates to the transport direction T by means of an actuation of the actuators 30, when a correct position of the band-type material 11 on the conveying section 12 is detected by means of the position sensor 36. This also applies mutatis mutandis to the coils L in the embodiment from FIG. 4, which are only energized as long as is necessary for a position correction of the band-type material 11.

Depending on the arrangement of a band position control device 24, a position sensor 36 may be arranged within the coating chamber 14 or also in a region upstream of the entry lock 20 or downstream of the exit lock 22, or even in the region of the entry lock 20 or the exit lock 22. This means that the vacuum-coating system 10 may comprise several of such position sensors 36 which are assigned to a respective band position control device in the various regions of the vacuum-coating system 10.

According to further embodiments of the band position control device 24, a so-called control roller (or a plurality of such control rollers) can be used in this case, which are shown in a simplified top view in FIG. 5 and in FIG. 6 and which are sold, for example, by the company EMG Automation GmbH (D-57482 Wenden, Germany). In this case, the band-type material 11 is guided via a control roller, wherein a certain wrap angle is set between the band-type material 11 and the control roller.

In the representations from FIG. 5 and FIG. 6, the transport direction, with which the band-type material 11 is guided via the control roller, is also designated as “T”, wherein the band-type material itself is not shown for the sake of simplicity. With the control roller 50 according to FIG. 5, the adjustment thereof relative to the band-type material 11 is carried out such that the control roller 50 is shifted along its longitudinal axis A perpendicular to the transport direction T. The control roller 50 functions proportionally in this manner. In contrast, an adjustment of the control roller 52 according to FIG. 6 is carried out such that the control roller 52 is rotated with its longitudinal axis A relative to the transport direction T, as is shown in FIG. 6 starting from a position in which the longitudinal axis A forms an angle of 90° with the transport direction T, for two exemplary deflections or rotated positions. The control roller 52 functions integrally in this manner.

With reference to the control rollers 50, 52, which are shown and explained in FIGS. 5 and 6, it can be noted that it is possible with a further (not shown) embodiment of the band position control device 24 to combine the functions of the control rollers 50, 52 and the adjustment option thereof with one another, in the form of a so-called lever control roller.

The use of at least one band position control device, as previously explained, makes it possible for the band-type material 11, which is within the coating chamber 14 placed under vacuum, to be moved along the transport direction T always with the optimal position on the conveying section 12 such that, e.g., an impact or contact is prevented between the band-type material 11 and the sidewalls of the coating chamber 14 or of the coating part 26. The same thing applies to the infeed of the band-type material 11 into the entry lock 20 or also to further movement of the band-type material 11 on the conveying section 12 after the exit from the exit lock 22.

As seen in the transport direction T of the band-type material 11, a further chemical cleaning device 42, which is traversed by the band-type material 11 before an infeed into the coating chamber 14, may be arranged upstream of the entry lock 20. The surfaces of the band-type material 11 are hereby cleansed or cleaned in preparation before the material is subjected to precision cleaning in the cleaning part 28 (under a vacuum).

The vacuum-coating system 10 comprises at least one flatness optimization device 39, which has a skin pass mill device 40 and is arranged upstream of the entry lock 20—as seen in the transport direction T of the band-type material 11. The band-type material 11 traverses the skin pass mill device 40 before it subsequently enters the coating chamber 14. The flatness on the surfaces of the band-type material 11 is adjusted to a desired value due to the contact with the rollers of the skin pass mill device 40, wherein potential flatness flaws on the surfaces of the band-type material 11 are simultaneously eliminated.

The vacuum-coating system 10 comprises at least one pair of trimming shears 38, upstream of the entry lock 20 of the coating chamber 14—as seen in the transport direction T of the band-type material 11. Adjacent thereto, at least one further position sensor 36 is provided, with which a position of the band-type material 11 on the conveying section 12 can be determined in a region upstream of the coating chamber 14 and thus also in the region of the trimming shears 38. This position sensor 36 is also connected to the control unit 34 with signals. Accordingly, it is possible by means of the control unit 34 to actuate the trimming shears 38 or place them into action as a function of signals of the position sensor 36.

The signaling connection between the control unit 34, on the one hand, and the position sensors 36, the band position control device 24, and the trimming shears 38, on the other hand, is simply indicated in FIG. 1 by a dotted-dashed line.

The trimming shears 38 are used to trim the band-type material 11 either at a band edge thereof or optionally on both band edges (i.e. on the left and right side edge of the band-type material 11), i.e. to make narrower through cutting and thereby to reduce the width of the band-type material 11 perpendicular to the transport direction T. The trimming shears 38 are then actuated, during operation of the vacuum-coating system 10 and upon a corresponding movement of the band-type material 11 along the conveying section 12, when it is detected by the position sensor 36 that a width of the band-type material 11 deviates from a predetermined setpoint and, for example, a widening is consequently too large. The trimming makes it possible for the band-type material 11 to obtain a uniform width over its length in the region upstream of the entry lock 20 and thus upstream of the infeed into the coating chamber 14, wherein said width is also optimally adapted to the width of the entry lock 20.

According to a further (not shown) embodiment of the invention, a stretching/bend-straightening device can also be a component of the flatness optimization device 39, as a supplement or alternative to the aforementioned skin pass mill device 40. The designation “K” and the assigned dashed rectangle in FIG. 1 simply indicate that the flatness optimization device 39 can also be formed as a compact unit, which comprises both a skin pass mill device 40 and a stretching/bend-straightening device. By means of the stretching/bend-straightening device and a placement of the rollers thereof, the flatness of the band-type material 11 is further improved on the surfaces thereof and optionally also a band extension is achieved, i.e. a lengthening of the band-type material 11 in the longitudinal direction thereof.

A coating is applied, e.g. a zinc layer, to at least one surface of the band-type material 11, preferably to both surfaces thereof, by moving the band-type material 11 through the coating chamber 14. This coating can take place within the coating part 26 according to the PVD principle. Once at least one surface of the band-type material 11 has been provided with a coating, e.g. with a zinc layer, the band-type material 11 is then wound back up again, as explained, by the second winding device 12.

Thus, the present invention provides for the application of a coating to a or the surface(s) of the band-type material 11 only at low temperatures without the material properties of the band-type material 11 being changed or impacted. This is particularly advantageous when the band-type material is a steel band, particularly in the form of a hot band, which has a structural proportion of at least 10% martensite.

### LIST OF REFERENCE NUMERALS

10 Vacuum-coating system

11 Band-type material

12 Conveying section

14 Coating chamber

16 Inlet region

18 Outlet region

20 Entry lock

22 Exit lock

24 Band position control device

24.2 Band position control device

24.3 Band position control device

24.4 Band position control device

26 Coating part

28 Cleaning part

29 Bearing/housing

30 Actuator

31 Contact roller(s)

32 Pressure sensor

33 Distance sensor

34 Control unit

35 Guide ruler(s)

36 Position sensor

38 Trimming shears

39 Flatness optimization device

40 Skin pass mill device

42 Chemical cleaning device

44 Storage unit

46 First winding device (infeed)

48 Second winding device (outfeed)

50 Control roller

52 Control roller

A Longitudinal axis (of a control roller 50, 52)

K Compact unit

L Coil(s)

T Transport direction (for the band-type material 11)

1-17. (canceled)

18. A vacuum-coating system or coating a band-type material of metal, comprising
a conveying section with transport means, particularly in the form of rollers, on which the band-type material is movable in a transport direction, wherein the transport means of the conveying section are formed such that the band-type material made of metal is movable thereupon with its width extension in horizontal alignment in the transport direction,
a coating chamber, in which the vacuum can be generated, wherein the coating chamber has an inlet region and an outlet region and thereby can be traversed by the band-type material along or on the conveying section in the transport direction,
an entry lock, which is provided in the inlet region of the coating chamber,
an exit lock, which is provided in the outlet region of the coating chamber, and
at least one band position control device, with which a position of the band-type material can be adjusted,
wherein
a position of the band-type material can be aligned, with the band position control device, as relates to a center of the conveying section, and
in that the band position control device is arranged within the coating chamber.

19. The vacuum-coating system according to claim 18, wherein a further band position control device is arranged upstream of the entry lock—as seen in the transport direction of the band-type material.

20. A vacuum-coating system for coating a band-type material of metal, comprising
a conveying section with transport means, particularly in the form of rollers, on which the band-type material is movable in a transport direction, wherein the transport means of the conveying section are formed such that the band-type material made of metal is movable thereupon with its width extension in horizontal alignment in the transport direction,
a coating chamber, in which the vacuum can be generated, wherein the coating chamber has an inlet region and an outlet region and thereby can be traversed by the band-type material along or on the conveying section in the transport direction,
an entry lock, which is provided in the inlet region of the coating chamber,
an exit lock, which is provided in the outlet region of the coating chamber, and
at least one band position control device, with which a position of the band-type material can be adjusted,
wherein
a position of the band-type material can be aligned, with the band position control device, as relates to a center of the conveying section, and
in that the band position control device is arranged upstream of the entry lock—as seen in the transport direction of the band-type material.

21. The Vacuum-coating system according to claim 20, wherein a further band position control device is provided, which is arranged within the coating chamber.

22. The vacuum-coating system according to claim 18, wherein the band position control device is arranged within the coating chamber, spaced apart from the entry lock and from the exit lock, respectively.

23. The vacuum-coating system according to claim 18, wherein the coating chamber is formed in multiple parts and has a coating part and a cleaning part, wherein the cleaning part is adjacent the coating part and is arranged upstream of the coating part—as seen in the transport direction of the band-type material—wherein the band position control device is provided at least in the coating part and/or in the cleaning part and/or in a region of the coating chamber between the coating part and the cleaning part.

24. The vacuum-coating system according to claim 23, wherein several band position control devices are provided in the coating chamber, wherein one band position control device each is arranged in the coating part, in the cleaning part, and/or in the region of the coating chamber between the coating part and the cleaning part.

25. The vacuum-coating system according to claim 18, wherein a further band position control device is arranged in the region of the entry lock.

26. The vacuum-coating system according to claim 18, wherein a further band position control device is arranged in the region of the exit lock.

27. The vacuum-coating system according to claim 18, wherein a further band position control device is arranged downstream of the exit lock—as seen in the transport direction of the band-type material.

28. The vacuum-coating system according to claim 18, wherein a further band position control device has actuators, which can be positioned at the band edges of the band-type material from both sides, in order to bring a band center of the band-type material in conformance with a center of the conveying section, preferably in that the actuators have rotatably mounted contact rollers, more preferably in that the actuators/contact rollers are actively connected to linear adjusting elements, which ensure a placement at the band-type material transversely as relates to the transport direction thereof.

29. The vacuum-coating system according to claim 18, wherein a band position control device comprises magnet elements for generating magnetic fields, by which an interaction can be created with a band-type material consisting of steel, in order to bring a band center of the band-type material in conformance with a center of the conveying section.

30. The vacuum-coating system according to claim 29, wherein the magnet elements are formed from permanent magnets.

31. The vacuum-coating system according to claim 29, wherein the magnet elements are formed from energizable coils.

32. The vacuum-coating system according to claim 18, wherein at least one position sensor is provided, with which a position of the band-type material on the conveying section can be determined, preferably in that a position sensor is arranged within the coating chamber and/or upstream of the coating chamber as seen in the transport direction of the band-type material.

33. The vacuum-coating system according to claim 18, wherein a control unit is provided, wherein a band position control device can be actuated and/or the band position control devices, which are arranged in the various regions of the vacuum-coating system, can be synchronized with one another, as a function of the signals of the position sensor.

34. A method for coating a band-type material made of metal, wherein the band-type material is moved with its width extension in horizontal alignment, via a conveying section, in a transport direction and is vacuum-coated within a coating chamber, in which a vacuum is applied, wherein a position of the band-type material is adjusted by a band position control device,
wherein
the band-type material made of metal is aligned with its band center as relates to a center of the conveying section by the band position control device, wherein the band position control device is arranged within the coating chamber.
